(19) United States
(12) Patent Application Publication
(10) Pub. No.: US 2005/0252767 A1
(43) Pub. Date: Nov. 17, 2005

(54) Sputtering device

(76) Inventor: Nobuyuki Takahashi, Sagamihara (JP)

Correspondence Address: WENDEROTH, LIND & PONACK, L.L.P., 2033 K STREET N. W., SUITE 800, WASHINGTON, DC, 20006-1021, US

(21) Appl. No.: 11/125,157

(22) Filed: May 10, 2005

(30) Foreign Application Priority Data
May 11, 2004 (JP) 2004-140708

(51) Int. Cl. C23C 14/32

(52) U.S. Cl. 204/298.18; 204/298.23; 204/298.27; 204/298.29; 204/298.26

(57) ABSTRACT

The object of the invention is to provide a sputtering device which can design uniformity of film thickness distribution by corresponding to ablation change of a target and can gain a stable film quality by uniformity of film growth components. Accordingly, a sputtering device according to this invention comprises at least: a vacuum container defining a vacuum space; a substrate holder for holding a substrate in said vacuum container; at least one sputtering cathode device which is provided with a cathode unit located at a position facing said substrate held on the substrate holder and arranged slantly at a specific angle to said substrate, and a means for moving cathode unit in parallel along said substrate; and a target installed on said cathode unit. The plural sputtering cathode devices can be also arranged at specific intervals in a circumferential direction of the substrate holder.

### BACKGROUND OF THE INVENTION

This invention relates to a sputtering device comprising at least a vacuum container defining a vacuum space, a substrate holder holding a substrate in the vacuum container, a cathode located at a position facing to the substrate held on the substrate holder, and a target installed on the cathode.

An ion beam sputter device disclosed in JP 2002-212724 A is provided with a vacuum container forming a space for processing a film formed object in the vacuum atmosphere, a plurality of ion sources for radiating ion beam to the vacuum container, a holder which is arranged within a movement area where every movement area of sputtering particles radiated from every target by radiation of the ion beam from every ion source are moved is overlapped and holds the film formed object, a shutter movably located in the vacuum container and preventing the sputtering particles from movement to the film formed object's side when it is positioned within a movement path connected between a certain target for pre-sputtering and the film formed object held on the holder, and a moving mechanism for moving the shutter to the movement path of the sputtering particles connected between a next target to be sputtered and the film formed object held on the holder after the pre-sputtering to the target for pre-sputtering.

JP 2003-247065 A discloses a thin film forming device comprising a vacuum container, a plasma generating means which generates plasma flow by introducing a gas for producing plasma, a target consisting of a thin forming material which is arranged concentrically to the plasma flow so as to come in contact with the plasma flow, a plurality of sputtering sources each of which is provided with a means for radiating particles of the thin film forming material from the target by using ions of the plasma flow, and a substrate table for installing a film formed substrate which is irradiated by the plasma flow. Besides, in this reference, the plasma generating means generates plasma by an electron cyclotron resonance discharge. Furthermore, each of the plural sputtering sources has a rotation means and a movement means. In the rotation means, rotation axis of the targets are arranged so as to intersect on a rotation center axis of the substrate table and so as to be slanted to the rotation center axis of the substrate table. Moreover, the movement means makes the substrate table move up and down.

As shown in the above mentioned references, in the case that a cathode with a target is provided slantly to a work such as a substrate, distance between the substrate and the cathode is different between at a center and at an outer edge portion in the substrate. Thus, when the substrate is rotated, the distance between the substrate and the cathode in the center of the substrate is usually constant, but the distance in the outer portion of the substrate is usually changed and the moving direction of the outer portion is changed so as to go toward or go away from the substrate. Accordingly, it is indicated that a specific characteristic of film is different between the positions in the substrate. Therefore, in JP 2003-247065 A discloses that the substrate table is moved up and down while rotated, but a mechanism for rotating and moving up/down the substrate table is complicated, as a result, disadvantage such that the costs are increased is arisen.

So far, it was confirmed that change of a film forming distribution is arisen by ablation degree of the target. Accordingly, disadvantage for a film thickness distribution and a film growth is tried to be resolved by making a size of the cathode larger than the substrate (about 1.4 times) and by limiting activity ratio of the target, it becomes a cause of an increase in costs to enlarge the target and limitation of the activity ratio.

### SUMMARY OF THE INVENTION

The object of the invention is to provide a sputtering device which can design uniformity of film thickness distribution by corresponding to ablation change of a target and can gain a stable film quality by uniformity of film growth components.

Accordingly, a sputtering device according to this invention comprises at least: a vacuum container defining a vacuum space; a substrate holder for holding a substrate in said vacuum container; at least one sputtering cathode device which is provided with a cathode unit located at a position facing said substrate held on the substrate holder and arranged slantly at a specific angle to said substrate, and a means for moving cathode unit in parallel along said substrate; and a target installed on said cathode unit.

Besides, it is preferred that the substrate holder is rotated at a specific speed.

Moreover, it is better that the plural sputtering cathode devices are arranged at specific intervals in a circumferential direction of the substrate holder.

Besides, the targets installed on the sputtering cathode units in the sputtering cathode devices consist of a same material. Accordingly, workability can be increased.

Furthermore, the targets installed on the sputtering cathode units in the sputtering cathode devices consist of different materials respectively. Accordingly, an alloy can be formed. Layers consisting of plural different materials respectively can be formed.

According to this invention, a cathode with a target is slanted to a rotating substrate and is moved along the substrate, so that a size of the target can be set no more than one of the substrate to achieve a decrease in costs, and a yield rate of the substrate can be increased because film thickness and film quality of the substrate is uniformed.

### BRIEF DESCRIPTION OF DRAWINGS

The various features of novelty which characterize the invention are pointed out with particularity in the claims annexed to and forming a part of this specification. For a better understanding of the invention, its operating advantages, and specific objects attained by its use, reference should be had to the accompanying drawings and descriptive matters in which there are illustrated and described preferred working modes of the invention.

FIG. 1 is an explanation diagram showing a sputtering device according to a first embodiment of this invention, and

FIG. 2 is an explanation diagram showing a sputtering device according to a second embodiment of this invention.

### DETAILED DESCRIPTION OF THE INVENTION

Hereinafter, embodiments of this invention are explained by referring drawings.

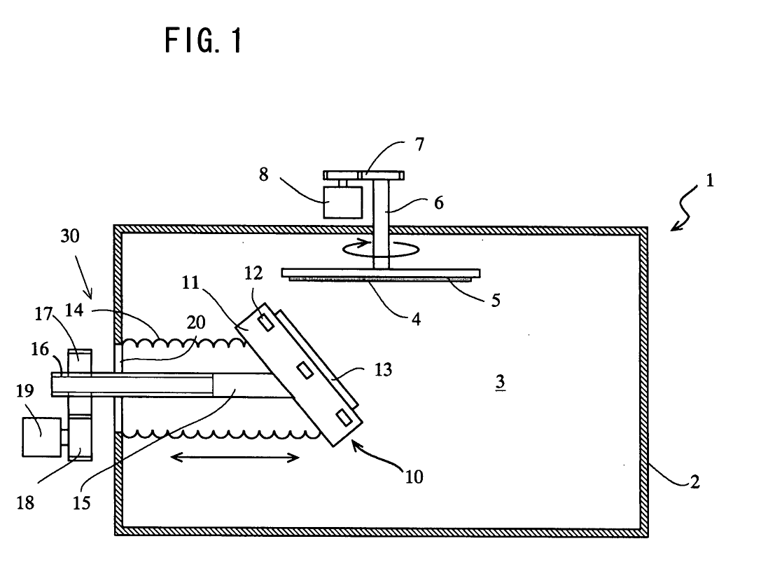

As shown in FIG. 1, a sputtering device 1 according to a first embodiment of this invention comprises at least a vacuum container 2 defining a vacuum space 3, a substrate holder 5 holding a substrate 4 as a work in the vacuum container 2, and a sputtering cathode device 10 for sputtering to the substrate 4 held on the substrate holder 5. According to thus constitution, basically, gas for sputtering is introduced into the vacuum container 3 and a minus voltage is applied to a target 13 provided in the sputtering cathode device 10, so that sputter particles are radiated from the target 13 to the substrate 4 installed in the vacuum container 3 to form a thin film on the substrate 4.

Besides, the substrate holder 5 is rotated at a specific speed via a rotation shaft 6 and gears 7 by a electric motor 8 as a drive means. The rotational speed is variable by an outer control device not shown in figures and is set at a specific rate according to materials or thickness of the thin film formed on the substrate 4.

The sputtering cathode device 10 is constituted of a cathode unit 11 arranged slantly at a specific angle to the substrate 4 and a movement unit 30 which moves the cathode unit 11 in parallel along a radial direction of the substrate 4.

The movement unit 30 is, in the first embodiment, constituted of a moving rod 15 which passes through an opening 20 formed in the vacuum container 2, whose one end is secured on the cathode unit 11 and which has a screw portion 16 formed spirally within a specific area at another end thereof, and a driving gear 17 including inner teeth screwed on the screw portion 16 and outer teeth to which rotation of an electric motor 19 is transmitted via a gear 18 in order to expand and contract the moving rod 15. Besides, moving speed of the movement unit 30 is controlled with control for the substrate holder 5 by the outer control device not shown in figures, and is set at an available speed according to materials or thickness of the thin film formed on the substrate 4. Note that the movement unit 30 may adopt a cylinder drive mechanism by an oil hydraulic operation, a water hydraulic operation and a pneumatic operation, and it is not limited means for driving if the moving rod 15 can be expanded and contracted.

A bellows portion 14 which is expanded and contracted with expansion and contraction of the moving rod 15 and sealed between the movement unit 30 and the vacuum space 3 is provided outside the moving rod 15.

Furthermore, the cathode unit 11 has a voltage supply mechanism that a minus high voltage is supplied via a harness not shown in figures arranged inside the bellows portion 14, and an insulation mechanism that insulates between the high voltage and the moving rod and so on, and further plural magnets 12 for increasing a density of plasma.

According to the above constitution, the substrate 4 that it is desired to form a thin film is installed on the substrate holder 5, the vacuum space 3 is formed by exhausting air from the vacuum container 2, the substrate holder 5 is rotated at a specific speed, gas for sputtering is introduced into the vacuum space 3, a high voltage is applied between the cathode unit 11 and the substrate 4, and the cathode unit 11 is moved along the substrate 4 at a specific speed back and forth, so that sputtering particles is radiated from the target 13 to form a thin film on the substrate 4. In thus method, since the distance between every part of the target 13 and every part of the substrate 4 is changed in succession, both of the film thickness and the film growth can be uniformed as a whole. Furthermore, change with time of the film thickness and the film growth by ablation of the target 13 can be amended and adjusted by speed control of the cathode unit 11, so that the target can be used efficiently.

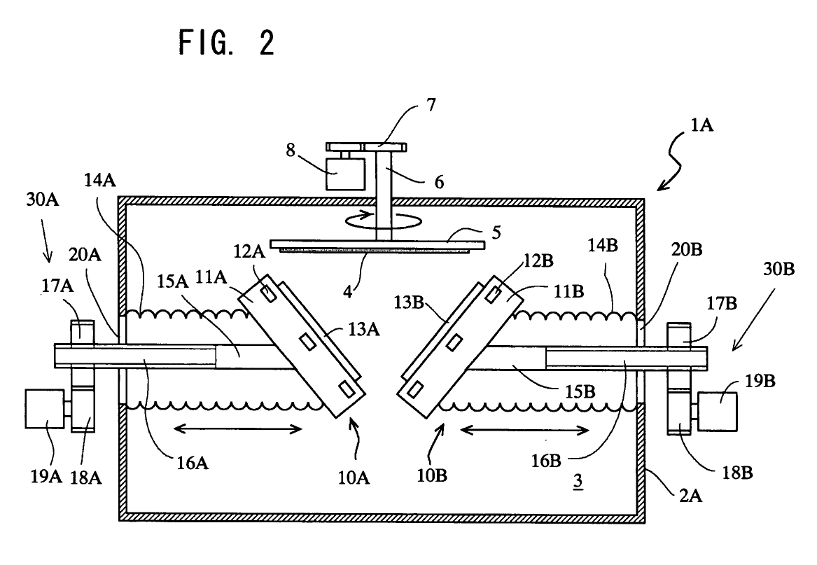

A sputtering device 1A according to the second embodiment of the invention as shown in FIG. 2 is characterized in that plural sputtering cathodes 10A, 10B which are similar to or the same as the sputtering cathode device 10 are provided at specific intervals in a circumferential direction of the substrate 4.

The sputtering cathode device 10A, 10B are constituted of cathode unit 11A, 11B which are arranged slantly at a specific angle to the substrate 4, and movement unit 30A, 30B which make the cathode units 11A, 11B in parallel along the radial direction of the substrate 4, respectively.

The movement units 30A, 30B are, in the second embodiment, constituted of moving rods 15A, 15B which pass through openings 20A, 20B formed in the vacuum container 2, whose one ends are secured on the cathode units 11A, 11B and which have screw portions 16A, 16B formed spirally within specific areas at the other ends thereof, and driving gear 17A, 17B including inner teeth screwed on the screw portions 16A, 16B and outer teeth to which rotation of electric motors 19A, 19B are transmitted via gears 18A, 18B in order to expand and contract the moving rods 15A, 15B, respectively. Besides, each moving speed of the movement units 30A, 30B is controlled with control for the substrate holder 5 by the outer control device not shown in figures, and is set at an available speed according to materials or thickness of the thin film formed on the substrate 4. Note that each of the movement units 30A, 30B may adopt a cylinder drive mechanism by an oil hydraulic operation, a water hydraulic operation and a pneumatic operation, and it is not limited means for driving if the moving rods 15A, 15B can be expanded and contracted.

Bellows portions 14A, 14B which are expanded and contracted with expansion and contraction of the moving rods 15A, 15B and sealed between the movement units 30A, 30B and the vacuum space 3 are provided outside the moving rods 15A, 15B, respectively.

Furthermore, each of the cathode units 11A, 11B has a voltage supply mechanism that a minus high voltage is supplied via a harness not shown in figures arranged inside each of the bellows portions 14A, 14B, and an insulation mechanism that insulates between the high voltage and the moving rod and so on, and further plural magnets 12A, 12B for increasing a density of plasma.

In the sputtering device 1A with the above mentioned constitution, when the targets 13A, 13B consist of the same material, growth speed of the film can be increased, and when the targets 13A, 13B consist of different materials respectively, the different layers can be laminated or an alloy can be formed.

1. A sputtering device comprising at least:
a vacuum container defining a vacuum space;
a substrate holder for holding a substrate in said vacuum container;
at least one sputtering cathode device which is provided with a cathode unit located at a position facing said substrate held on the substrate holder and arranged slantly at a specific angle to said substrate, and a means for moving cathode unit in parallel along said substrate; and
a target installed on said cathode unit.

2. A sputtering device according to claim 1, wherein said substrate holder is rotated at a specific speed.

3. A sputtering device according to claim 1, wherein said plural sputtering cathode devices are arranged at specific intervals in a circumferential direction of said substrate holder.

4. A sputtering device according to claim 2, wherein said plural sputtering cathode devices are arranged at specific intervals in a circumferential direction of said substrate holder.

5. A sputtering device according to claim 3, wherein said targets installed on said cathode units consist of a same material.

6. A sputtering device according to claim 4, wherein said targets installed on said cathode units consist of a same material.

7. A sputtering device according to claim 3, wherein said targets installed on said cathode units consist of different materials respectively.

8. A sputtering device according to claim 4, wherein said targets installed on said cathode units consist of different materials respectively.
